(19) United States
(12) Patent Application Publication
(10) Pub. No.: US 2024/0222211 A1
(43) Pub. Date: Jul. 4, 2024

(54) IC DIE PACKAGES WITH LOW CTE DIELECTRIC MATERIALS

(71) Applicant: Intel Corporation, Santa Clara, CA (US)

(72) Inventors: Peumie Abeyratne Kuragama, Chandler, AZ (US); Dilan Seneviratne, Phoenix, AZ (US); Whitney Bryks, Tempe, AZ (US)

(73) Assignee: Intel Corporation, Santa Clara, CA (US)

(21) Appl. No.: 18/091,270

(22) Filed: Dec. 29, 2022

(51) Int. Cl. H01L 23/16; H01L 23/00; H01L 23/15; H01L 23/538

(52) U.S. Cl. CPC H01L 23/16; H01L 23/15; H01L 23/5383; H01L 23/562

(57) ABSTRACT

IC device packages including a low-CTE polymer dielectric build-up material comprising a filler having a negative CTE. Low CTE build-up materials may have a CTE less than 10 ppm/K below the glass transition temperature (T_{g}) of the polymer resin containing the filler. With a negative CTE filler, polymer resin expansion during thermal cycles (e.g., resin cure) may be at least partially countered through negative thermal expansion of the filler.

### BACKGROUND

Monolithic integrated circuit (IC) fabrication has restrictions that may limit a final product's performance, and thus different versions of IC die (dis)integration are being investigated. To date however, these techniques and architectures generally suffer from certain drawbacks such as high cost, lower insertion efficiency, and increased z-height.

IC die disintegration techniques rely on advances in multi-die integration at the package level. In electronics manufacturing, IC packaging is a stage of semiconductor device fabrication in which an IC that has been monolithically fabricated on a chip (or die) comprising a semiconducting material is assembled into a “package” that can protect the IC chip from physical damage and support electrical contacts that connect the IC to a scaled host component, such as an organic package substrate, or a printed circuit board. Multiple chips can be similarly assembled, for example, into a multi-chip package (MCP).

Such multi-chip architectures may advantageously combine IC chips from heterogeneous silicon processes and/or combine small dis-aggregated chips from identical silicon processes. However, there are many challenges with integrating multiple IC die into such a chip-scale unit. For example, inter-die fill material, such as an epoxy-based mold material can introduce high stress particularly if the fill material has a significantly different thermal expansion coefficient. In alternative inter-die fill techniques where inter-die spaces are filled with inorganic material to mitigate stress-induced failure, the gap-fill deposition techniques (e.g., PECVD) can be prohibitively slow and/or expensive.

Accordingly, alternative IC die package architectures, and techniques associated with those architectures, may therefore be commercially advantageous.

### BRIEF DESCRIPTION OF THE DRAWINGS

The material described herein is illustrated by way of example and not by way of limitation in the accompanying figures. For simplicity and clarity of illustration, elements illustrated in the figures are not necessarily drawn to scale. For example, the dimensions of some elements may be exaggerated relative to other elements for clarity. Further, where considered appropriate, reference labels have been repeated among the figures to indicate corresponding or analogous elements. In the figures:

FIG. 1 illustrates a flow diagram of methods for forming a packaged IC device including a low coefficient of thermal expansion (CTE) dielectric build-up material, in accordance with some embodiments;

FIG. 2 illustrates a cross-sectional view of a low-CTE substrate, in accordance with some embodiments;

FIGS. 3A and 3B are cross-sectional views of a low-CTE dielectric build-up material in contact with a surface of a package substrate, in accordance with some embodiments;

FIG. 3C illustrates a reduction in filler particle volume with curing of the low-CTE dielectric buffer material;

FIG. 4 is a cross-sectional view of an IC die package with a first metallization level, in accordance with some embodiments;

FIGS. 5A and 5B are cross-sectional views of another layer of dielectric build-up material, in accordance with some embodiments

FIG. 6 is a cross-sectional view of an IC die package including multiple levels of metallization embedded in dielectric build-up material, in accordance with some embodiments;

FIG. 7 is a cross-section view of IC die attachment to an IC die package, in accordance with some embodiments;

FIG. 8 is a cross-sectional view of a packaged IC device including IC die coupled to a package substrate through levels of metallization embedded within low-CTE dielectric build-up material, in accordance with some embodiments;

FIG. 9 illustrates a system including the IC device structure illustrated in FIG. 8 attached to a host component with interconnect features, in accordance with some embodiments;

FIG. 10 illustrates a mobile computing platform and a data server machine employing an IC device including low-CTE polymer dielectric build-up material, in accordance with some embodiments; and

FIG. 11 is a functional block diagram of an electronic computing device, in accordance with some embodiments.

### DETAILED DESCRIPTION OF EXEMPLARY EMBODIMENTS

Embodiments are described with reference to the enclosed figures. While specific configurations and arrangements are depicted and discussed in detail, this is done for illustrative purposes only. Persons skilled in the relevant art will recognize that other configurations and arrangements are possible without departing from the spirit and scope of the description. It will be apparent to those skilled in the relevant art that techniques and/or arrangements described herein may be employed in a variety of other systems and applications other than what is described in detail herein.

Reference is made in the following detailed description to the accompanying drawings, which form a part hereof and illustrate exemplary embodiments. Further, it is to be understood that other embodiments may be utilized and structural and/or logical changes may be made without departing from the scope of claimed subject matter. It should also be noted that directions and references, for example, up, down, top, bottom, and so on, may be used merely to facilitate the description of features in the drawings. Therefore, the following detailed description is not to be taken in a limiting sense and the scope of claimed subject matter is defined solely by the appended claims and their equivalents.

In the following description, numerous details are set forth. However, it will be apparent to one skilled in the art, that embodiments may be practiced without these specific details. In some instances, well-known methods and devices are shown in block diagram form, rather than in detail, to avoid obscuring the embodiments. Reference throughout this specification to “an embodiment” or “one embodiment” or “some embodiments” means that a particular feature, structure, function, or characteristic described in connection with the embodiment is included in at least one embodiment. Thus, the appearances of the phrase “in an embodiment” or “in one embodiment” or “some embodiments” in various places throughout this specification are not necessarily referring to the same embodiment. Furthermore, the particular features, structures, functions, or characteristics may be combined in any suitable manner in one or more embodiments. For example, a first embodiment may be combined with a second embodiment anywhere the particular features, structures, functions, or characteristics associated with the two embodiments are not mutually exclusive.

As used in the description and the appended claims, the singular forms “a”, “an” and “the” are intended to include the plural forms as well, unless the context clearly indicates otherwise. It will also be understood that the term “and/or” as used herein refers to and encompasses any and all possible combinations of one or more of the associated listed items.

The terms “coupled” and “connected,” along with their derivatives, may be used herein to describe functional or structural relationships between components. These terms are not intended as synonyms for each other. Rather, in particular embodiments, “connected” may be used to indicate that two or more elements are in direct physical, optical, or electrical contact with each other. “Coupled” may be used to indicated that two or more elements are in either direct or indirect (with other intervening elements between them) physical or electrical contact with each other, and/or that the two or more elements co-operate or interact with each other (e.g., as in a cause-and-effect relationship).

The terms “over,” “under,” “between,” and “on” as used herein refer to a relative position of one component or material with respect to other components or materials where such physical relationships are noteworthy. For example, in the context of materials, one material or layer over or under another may be directly in contact or may have one or more intervening materials or layers. Moreover, one material between two materials or layers may be directly in contact with the two materials/layers or may have one or more intervening materials/layers. In contrast, a first material or layer “on” a second material or layer is in direct contact with that second material/layer. Similar distinctions are to be made in the context of component assemblies.

As used throughout this description, and in the claims, a list of items joined by the term “at least one of” or “one or more of” can mean any combination of the listed terms. For example, the phrase “at least one of A, B or C” can mean A; B; C; A and B; A and C; B and C; or A, B and C.

Unless otherwise specified in the specific context of use, the term “predominantly” means more than 50%, or more than half. For example, a composition that is predominantly a first constituent means more than half of the composition is the first constituent (e.g., <50 at. %). The term “primarily” means the most, or greatest, part. For example, a composition that is primarily a first constituent means the composition has more of the first constituent than any other constituent. A composition that is primarily first and second constituents means the composition has more of the first and second constituents than any other constituent. The term “substantially” means there is only incidental variation. For example, composition that is substantially a first constituent means the composition may further include <1% of any other constituent. A composition that is substantially first and second constituents means the composition may further include <1% of any constituent substituted for either the first or second constituent.

IC device packages including a low coefficient of thermal expansion (CTE) dielectric build-up material are described herein. For such IC device packages, a polymer build-up material including fillers advantageously having a negative CTE may be placed in direct contact with a package substrate. With negative CTE filler, polymer resin expansion during thermal cycles, for example of up to the resin cure temperature, may be at least partially countered through negative thermal expansion of the filler. Such a low-CTE polymer dielectric build-up material is well suited to package substrates having a low CTE, such as a glass substrate. Bonding between a glass substrate and the low-CTE polymer build-up material may be enhanced through a resin formulation that increases hydrogen bonding at the substrate interface.

In some examples, a polymer dielectric build-up material has a bulk coefficient of thermal expansion that is a better match with a glass substrate that has a significantly lower CTE than conventional copper-cored substrates. Such a build-up material may therefore also be a better CTE match with inorganic dielectric materials of the type deposited with a high-density plasma (HDP), as well as silicon IC die substrates. In accordance with some embodiments the low CTE build-up materials described herein have a CTE less than 10 ppm/K below the glass transition temperature (T_{g}) of the polymer resin containing the filler particles.

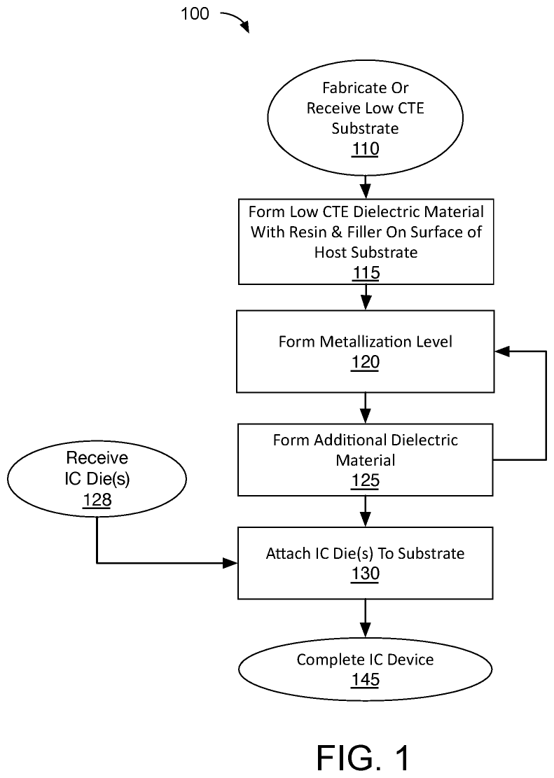

A number of different assembly and/or fabrication methods may be practiced to form an IC device having a dielectric build-up material with one or more of the features or attributes described herein. FIG. 1 illustrates a flow diagram of methods 100 for forming an IC device package including a low-CTE polymer dielectric build-up material.

Methods 100 begin at input 110, where an IC device package substrate is fabricated, or received as a preform that has been fabricated upstream of methods 100. The substrate is advantageously of a material with a low CTE, rather than a copper core substrate. The substrate may be a cored substrate with the low CTE material at the core, or the substrate may be a coreless substrate with the low CTE material comprising the bulk of the substrate. Any substrate fabrication process may be employed to fabricate the package substrate received at input 110.

In some embodiments, the IC die package substrate has a CTE below that of conventional Cu-based cored substrates that typically include a resinous composite with a CTE exceeding 15 ppm/K. For example, whereas a Cu-based cored substrate may have a CTE ranging from over 15 (below T_{g}) to 70 ppm/K, or more (above T_{g}), package substrate 201 is predominantly a material with a CTE below 15 ppm/K, advantageously below 10 ppm/K, and may be less than 5 ppm/K.

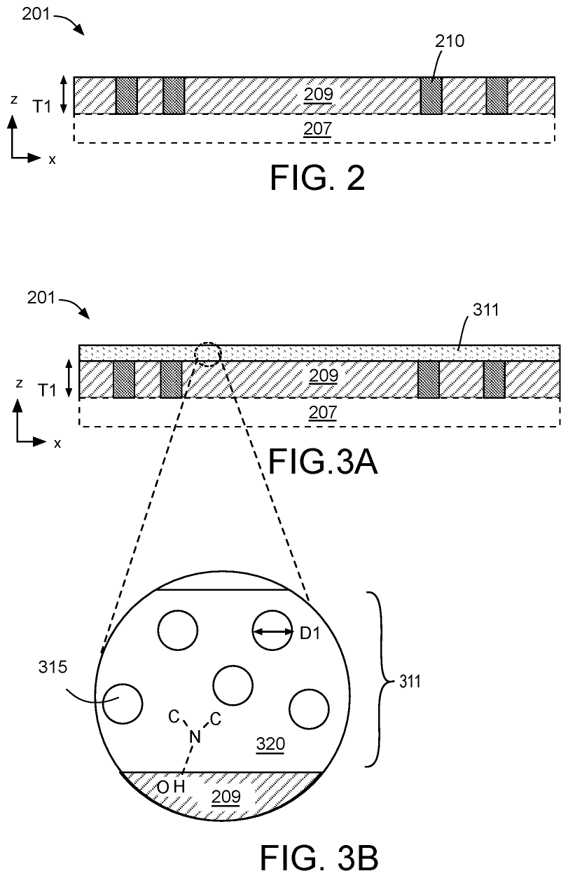

In the example illustrated in FIG. 2, a package substrate 201 comprises a bulk glass wafer or panelized glass substrate 209. Glass substrate 209 is at least primarily, and may be substantially, amorphous glass. Glass substrate 209 advantageously has a flatness comparable to that of a silicon substrate, and may have large dimensions suitable for large format panel processing, etc. Glass substrate 209 may be supported by a carrier or handle substrate 207, such as any of those known to be suitable in the industry. Glass substrate 209 may consist of only glass, or it may have one or more thin film material layers on one or both of a front side or back side of glass substrate 209. Glass substrate 209 is advantageously predominantly silica (e.g., silicon and oxygen). Various dopants (e.g., carbon, boron, phosphorus) may be present in glass substrate 209 (e.g., borosilicate glass, etc.) as embodiments herein are not limited in this respect. In exemplary embodiments, glass substrate 209 has a CTE of ˜3 ppm/K. Although glass is one example, package substrate 201 may be primarily of an alternative material with a similarly low CTE, such as, but not limited to, silicon.

Glass substrate 209 may have any thickness T1. However, in some embodiments, thickness T1 is at least 20 μm and may be in the range of 20-200 μm, or more. One or more through substrate vias (TSVs) 210 may extend through substrate thickness T1. For glass substrate embodiments, TSVs 210 may be more specifically referred to as through-glass vias (TGVs). TSVs 210 may comprise any metallization suitable as a conductive path through substrate thickness T1. In some examples TSVs 210 are at least partially filled with copper.

Returning to FIG. 1, methods 100 continue at block 115 with the formation of a low-CTE polymer dielectric build-up material over at least one side of the package substrate. The low-CTE build-up material may be applied as mold compound, or as a spin-on material, for example. For such embodiments, the low-CTE build-up material is applied to the substrate in a wet/uncured state and then cured at a temperature above T_{g} where cross-linking of the polymer matrix occurs. As used herein a “low-CTE” dielectric build-up material has a coefficient of thermal expansion less than 10 ppm/K below T_{g}. In advantageous embodiments, the build-up material deposited at block 115 has a coefficient of thermal expansion less than 8 ppm/K below T_{g} (e.g., 6-8 ppm/K). The low-CTE material is therefore suitable for a low CTE substrate, such as glass, which may have a CTE around 3 ppm/K, for example. Relative to a conventional dielectric build-up material, the low-CTE material reduces mismatch in thermal expansion so that less stress is generated in the substrate (and build-up), particularly during a cure process. With lower stress at the interface of the build-up material, warpage of the substrate and/or cracks in the substrate may be reduced. Delamination of the build-up material may also be reduced.

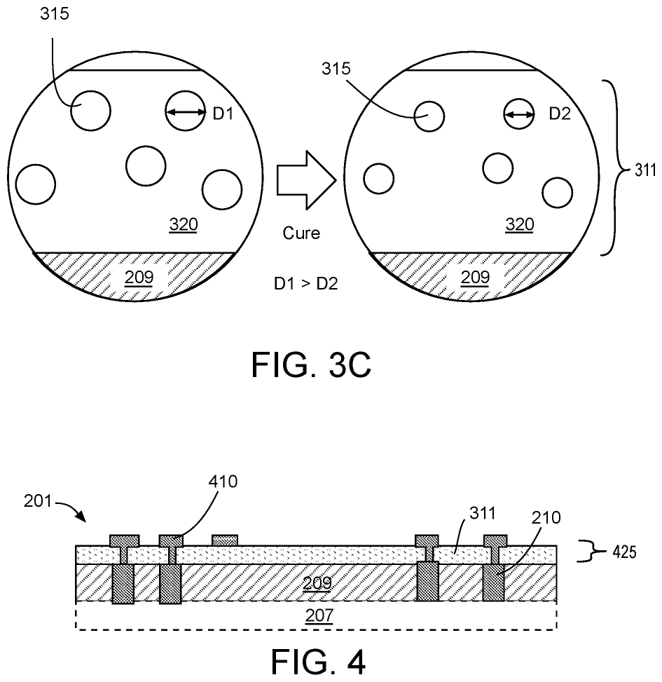

FIG. 3A further illustrates application of a wet layer of an exemplary low-CTE polymer dielectric build-up material 311 directly upon substrate 209. As further illustrated in the expanded view of FIG. 3B, dielectric build-up material 311 is a composite including particles of filler material 315 within a matrix material 320. In exemplary embodiments, matrix material 320 is an organic polymer resin, which has a (positive) CTE of some magnitude dependent upon resin composition.

Matrix material 320 may comprise an epoxy resin, for example. The epoxy resin may be an acrylate of novolac such as epoxy phenol novolacs (EPN) or epoxy cresol novolacs (ECN)), for example. In some embodiments, the epoxy resin is a bisphenol-A epoxy resin, for example including epichlorohydrin. In other embodiments, the epoxy resin is bisphenol-F epoxy resin (with epichlorohydrin). In other embodiments, the epoxy resin is an aliphatic epoxy resin, which may be monofunctional (e.g., dodecanol glycidyl ether), difunctional (butanediol diglycidyl ether), or have higher functionality (e.g., trimethylolpropane triglycidyl ether). In still other embodiments, the epoxy resin is a glycidylamine epoxy resin, such as triglycidyl-p-aminophenol or N,N,N′,N′-tetraglycidyl-bis-(4-aminophenyl)-methane.

Matrix material 320 may include one or more components in addition to epoxy resin that increases adhesion of dielectric buildup material 311 to substrate 209. For exemplary embodiments where substrate 209 is predominantly glass, delamination of buildup material 311 may be reduced through the addition of components that increase hydrogen bonding with Si—O—H (silanol) groups on the surface of substrate 209. Substituents or additives to a main resin (e.g., epoxy) may increase such hydrogen bonding. In the example illustrated in FIG. 3B, matrix material 320 comprises nitrogen containing groups, such as an imine, amine or pyridine with one exemplary additive being polyimides (and derivatives thereof). In other embodiments, matrix material 320 may instead comprise oxygen containing groups, such as ketones or esters with one exemplary additive being polyesters (and derivatives thereof).

Thermal and mechanical stability of dielectric build-up material 311 is important to minimize and tolerate mechanical stress generated during thermal processes, such as those employed during cure. Hence, apart from improving adhesion to glass substrates, greater thermal and mechanical stability of matrix material 320 can be achieved through the incorporation of polyimide (and derivatives thereof) within the resin. In exemplary embodiments the polymer resin comprises no more than 50 wt % epoxy. For such embodiments, the polymer resin may further comprise at least 10 wt % polyimide and may advantageously comprise 20 wt % polyimide, or more, so that matrix material 320 is a resin system with an epoxy:polyimide ratio under 5:1 and perhaps 5:2, or less.

Dielectric build-up material 311 further comprises particles of filler material 315 having a predetermined and/or controlled distribution of particle volumes, for example associated with a mean particle diameter D1. Filler particle diameter D1 may be selected to be suitable for topographic features that will be formed within dielectric build-up material after cure. For example, particle diameter D1 may be selected to be smaller than a minimum feature or gap dimension to ensure filler particles are present within topographic features of such dimension. In examples, particle diameter D1 is less than 1 μm. In some embodiments, particle diameter D1 is at least 0.1 μm to ensure each particle as a volume sufficient to impart a desirable volumetric reduction to the composite material at a level of filler content that avoids rendering the wet build-up material too viscous for the application process.

In exemplary embodiments, filler material 315 displays negative thermal expansion (i.e., CTE<0) over a temperature range anywhere below the glass transition temperature (T_{g}) of dielectric build-up material 311. A reduction in volume of filler material 315 within this temperature range at least partially counters the positive thermal expansion of matrix material 320 over the temperature range. Negative thermal expansion is a physicochemical phenomenon associated with material composition and/or microstructure of filler material 315. FIG. 3C depicts pre-cure and post-cure states dielectric build-up material 311 during which the volumetric ratio of filler material 315 to matrix material 320 decreases from a first pre-cure ratio to second post-cure ratio, for example as a function of filler particle diameter D1 contracting to a smaller particle diameter D2. The cure temperature may be in the range of 180° C.-250° C., for example. As particles of filler material 315 reduce their volume, matrix material 320 may fill in the vacancies without inducing significant stress. Accordingly, space generated by a filler volume reduction counters expansion of the resin system so that an overall magnitude of thermal expansion of dielectric build-up material 311 is reduced.

Reduction in filler volume upon heating may be by a framework-type mechanism and/or a phase transition mechanism, either of which can be effective for implementing embodiments herein. In advantageous embodiments, particles of filler material 315 undergo a microstructural ordering within the temperature range where the filler material displays negative CTE with a framework-type mechanism being advantageous over phase transition mechanisms because phase transition is typically limited to a narrower temperature range. In a framework-type mechanism (poly)crystalline filler material lattices display net negative thermal expansion due to dynamic deformation (vibrational mode) that consumes open spaces in the crystal lattice thereby reducing overall volume. Such a mechanism is distinct from phase change where filler material may transition between two microstructural phases (e.g., α and γ). In some embodiments, filler material 315 undergoes both framework and phase transition mechanisms.

In some embodiments, filler material 315 is a compound of a transition metal, such as, but not limited to titanium, zirconium, hafnium, vanadium, niobium, tantalum, yttrium, niobium, molybdenum, tungsten, or ruthenium. Several transition metal compounds are known to have layered microstructures amenable to framework-type and/or phase transition mechanisms leading to a negative CTE. In some exemplary embodiments, filler material 315 is a compound of zirconium such as zirconium phosphate (e.g., Zr(HPO₄)₂) or a derivative thereof comprising one or more organic elements other than phosphorus, such as nitrogen, sulfur (e.g., Zr₂SP₂O₁₂) or another chalcogen (e.g., Se or Te). Zr₂SP₂O₁₂, for example, possesses a negative CTE of significant magnitude over a wide range of temperatures (e.g., up 800° C.) and undergoes both framework-type and phase transition (e.g., α and γ) mechanisms.

The filler content within the low-CTE dielectric build-up material may vary as a function of the magnitude of the negative CTE of the filler, the magnitude of the positive CTE of the polymer resin, and the magnitude of the CTE of the low-CTE substrate. In some exemplary embodiments, dielectric material 311 comprises no more than 65 wt % filler material 315. Filler material with a more negative CTE may enable lower filler weight percentages (e.g., 50-60 wt %), facilitating a lower wet material viscosity.

FIG. 4 is a cross-sectional view of IC die package 201 with a first metallization level 425 formed within a layer of dielectric build-up material 311, in accordance with some embodiments. In this example first metallization level 425 comprises a plurality of metallization features 410 embedded within build-up material 311, some of which are in direct contact with TSVs 210. While metallization features 410 may have any composition(s) of sufficient electrical conductivity, in exemplary embodiments, metallization features 410 are predominantly copper (Cu). In other examples, metallization features 410 are predominantly other than Cu, such as, but not limited to predominantly Ru, or predominantly W.

Returning to FIG. 1, methods 100 continue with the formation of a metallization level at block 120. Any known metallization technique may be practiced at block 120 as embodiments herein are not limited in this respect. Another dielectric build-up material layer may be further formed at block 125. In some embodiments, the same low-CTE dielectric material formed at block 115 is also formed at block 125. In alternative embodiments, a different dielectric material (e.g., of CTE over 10 ppm/K) is formed at block 125. Blocks 120, 125 may be practiced any number of times to form any number of metallization levels over one or both sides of a package substrate.

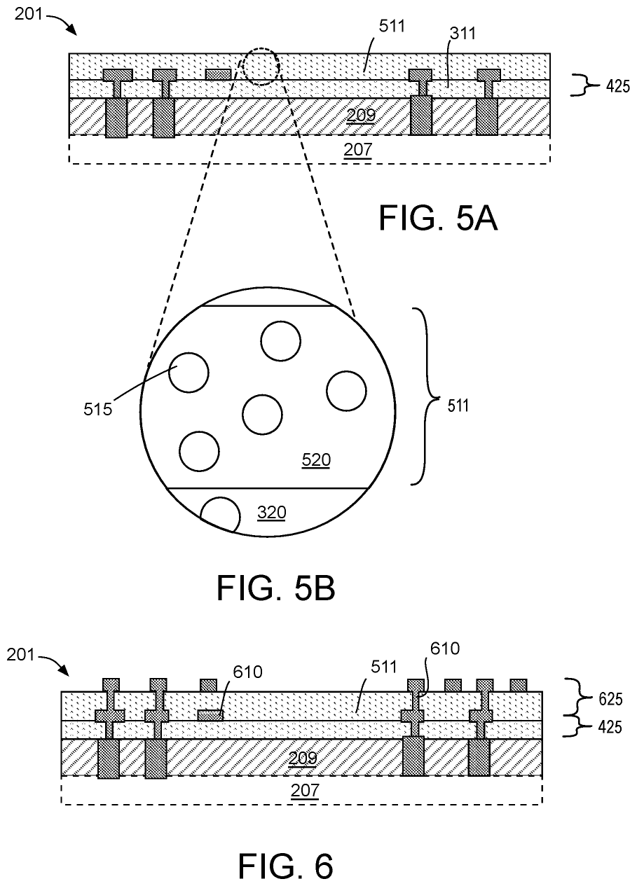

In the example shown in FIG. 5A, a dielectric build-up material layer 511 has been deposited over, and in direct contact with, dielectric build-up material layer 311. In some embodiments, dielectric build-up material layer 511 is also a low-CTE dielectric build-up material and may have substantially the same composition as dielectric build-up material layer 311, for example. In other embodiments, dielectric build-up material layer 511 is not a low-CTE dielectric build-up material and instead comprises particles of an alternative filler material 515 (FIG. 5B), such as silica, that has a positive CTE. For such embodiments, matrix material 520 may have the same composition as matrix material 320, or not. In some examples, matrix material 520 has a higher epoxy content than matrix material 320. Although a dielectric build-up material layer 511 with positive CTE filler material may have a larger mismatch with a low-CTE substrate 209, the presence of low-CTE dielectric build-up material layer 311 may act as a buffer mitigating deleterious effects of greater CTE mismatch between build-up material layer 511 and substrate 209.

FIG. 6 further illustrates the addition of another metallization level 625 comprising some exemplary metallization features 610 embedded within build-up material 511, some of which are in direct contact with metallization features 410.

Returning to FIG. 1, methods 100 continue at block 130 where one or more IC dies received at input 128 are attached to the package substrate. Each IC die received may have been fabricated upstream of methods 100 according to any technique known to be suitable. The IC die received at input 128 may be fully functional ASICs, or may be chiplets or tiles that have a more limited functionality supplementing the function of one or more other IC die. A chiplet or tile may, for example, be any of a wireless radio circuit, microprocessor core, electronic memory circuit, floating point gate array (FPGA), power management and/or power supply circuit, or include a MEMS device. The package assembly may then be completed at output 145 accordingly to any known techniques.

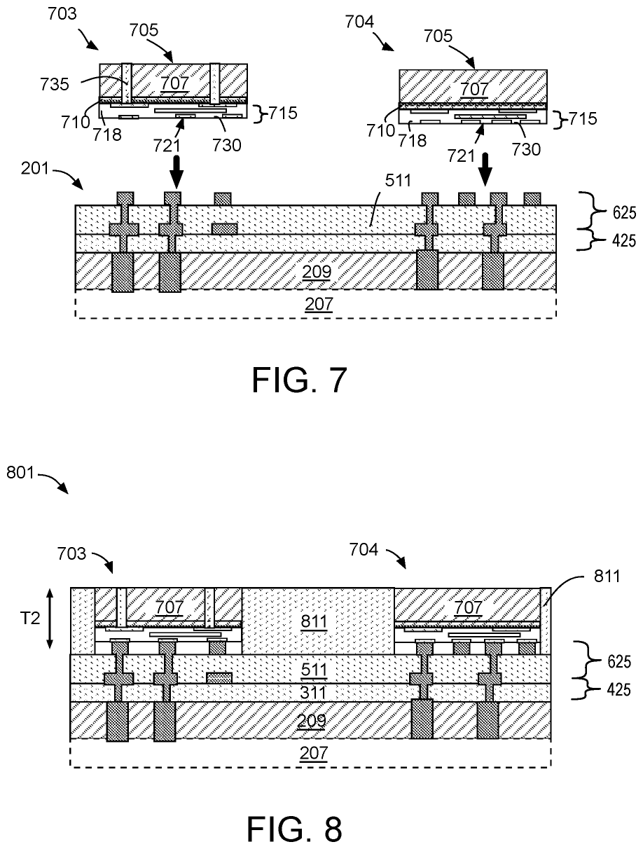

In the example illustrated in FIG. 7, a pair of IC die 703, 704 are attached to package substrate 201 with the arrows in FIG. 7 representing positional alignment of metal features on package substrate 201 to corresponding metallization features on IC dies 703, 704.

Each of IC die 703 and IC die 704 may include one or more banks of active repeater circuitry to improve multi-chip interconnects (e.g., network-on-chip architectures). A repeater bank may, for example, support 2000+ signals within an IC die area of 0.4 mm². In other examples, IC die 703 and/or IC die 704 includes clock generator circuitry or temperature sensing circuitry. In other examples, IC die 703 and/or IC die 704 includes one or more ESD banks. In other examples, IC die 703 and/or IC die 704 includes logic circuitry that, along with other IC die implements 3D logic circuitry (e.g., mesh network-on-chip architectures). In other examples, at least one of IC die 703 and/or IC die 704 includes microprocessor core circuitry, for example comprising one or more shift registers. In still other examples, at least one of IC die 703 and/or IC die 704 includes electronic memory (e.g., DRAM) circuitry, for example comprising a plurality of volatile or non-volatile bit-cells.

IC die 703 and IC die 704 each include a device layer 710 over substrate material 707, and metallization levels 715 on the front side 721. Device layer 710, substrate material 707 and metallization levels 715 may have any of the properties known to be suitable for an IC die. In some examples, substrate material 707 is silicon. In other examples, substrate material 707 is an alternative crystalline material, such as, but not limited to, germanium, SiₓGe₁₋ₓ, GeₓSn₁₋ₓ or silicon carbide. Device layer 710 may be homogenous with substrate material 707, or not (e.g., a transferred substrate). Device layer 710 (and a homogeneous IC die substrate material 707) may include any semiconductor material such as, but not limited to, predominantly silicon (e.g., substantially pure Si) material, predominantly germanium (e.g., substantially pure Ge) material, or a compound material comprising a Group IV majority constituent (e.g., SiGe alloys, GeSn alloys). In other embodiments, IC device layer 710 is a Group III-V material comprising a Group III majority constituent and a Group IV majority constituent (e.g., InGaAs, GaAs, GaSb, InGaSb). IC die device layer 710 may have a thickness of 50-1000 nm, for example. IC die device layer 710 need not be a continuous layer of semiconductor material, but rather may include active regions of semiconductor material surrounded by field regions of isolation dielectric.

In the illustrated arrangement, front side 721 of IC dies 703, 704 bond with, or otherwise attach to, a side of package substrate 201. In the illustrated example, IC die 703 further illustrates an example where TSVs 735 extend through IC die substrate material 707 to a back side 705 of IC die 703.

FIG. 8 illustrates a package fill material 811 (e.g., mold material). In exemplary embodiments, the package fill material 811 is an electrical insulator. However, in alternative embodiments, package fill material 811 may instead comprise an electrical conductor (e.g., a metal or metallic compound), or a semiconductor (e.g., amorphous silicon). Although composition may vary with implementation, in exemplary embodiments package fill material 811 is an organic dielectric material, such as an epoxy with one or more fillers. In some examples, fill material 811 is a low-CTE dielectric material, for example having a composition substantially the same as that of build-up material 311. In some alternative examples, fill material 811 has a larger CTE than build-up material 311 (e.g., comprising silica filler).

In the example illustrated in FIG. 8, a grind, polish, or other planarization process has removed any overburden of package fill material 811. Following planarization, package fill material 811 may have a thickness T2 that is substantially equal to that of IC die 703 and/or IC die 704. In some embodiments, completion of packaged device 801 entails stacking another IC die upon one or more of the IC dies already in packaged IC device 801. First level interconnects (FLI) may be formed on exposed surfaces of conductive features of packaged IC device 801 in preparation for a next level of assembly. In exemplary embodiments, solder features are formed as the FLI.

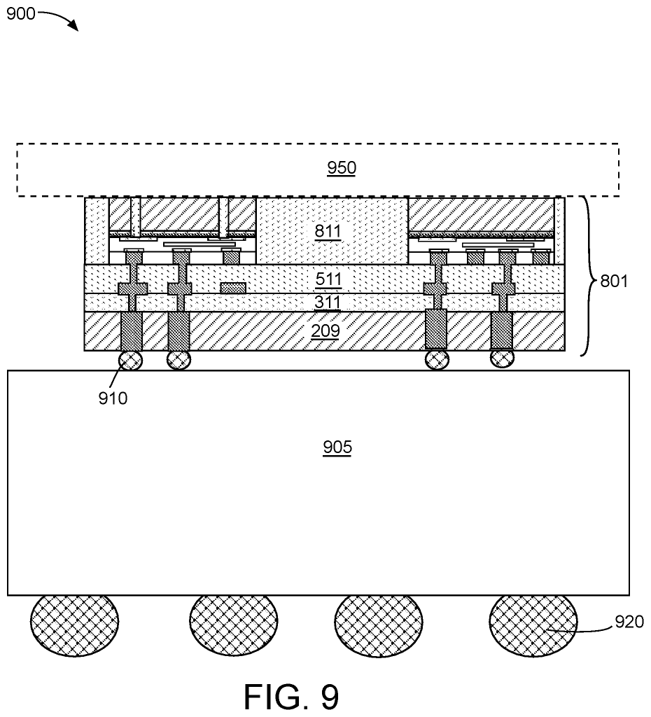

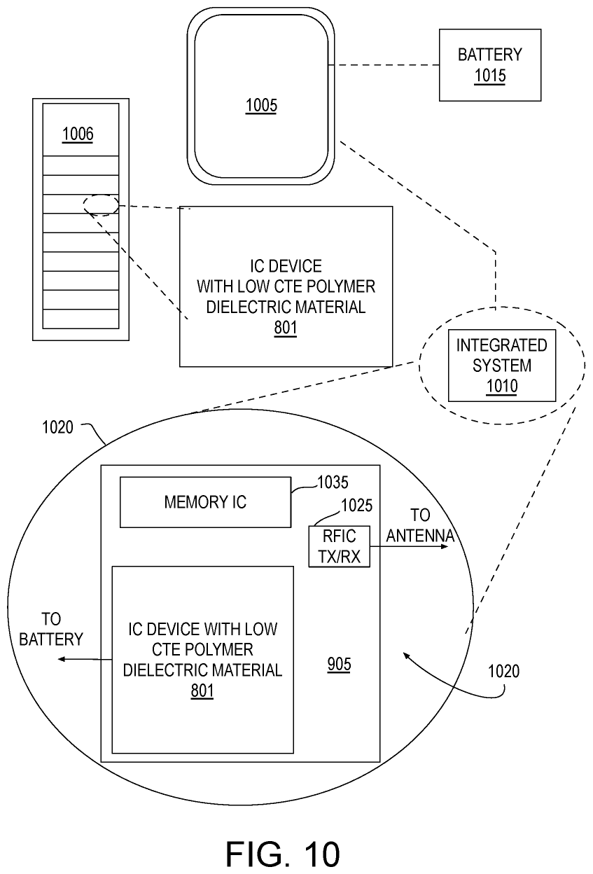

FIG. 9 illustrates a system including packaged IC device 801 attached to a host component 905 by reflowing FLI features 910. In exemplary embodiments, FLI features 910 are solder (e.g., SAC) microbumps although other interconnect features are also possible. In some embodiments, host component 905 is predominantly silicon. Host component 905 may also comprise one or more alternative materials known to be suitable as interposers or package substrates (e.g., an epoxy preform, cored or coreless laminate board, etc.). Host component 905 may include one or more metallized redistribution levels (not depicted) embedded within a dielectric material. Host component 905 may also include one or more IC die embedded therein. For example, an IC interconnect bridge (not depicted) may be embedded within metallized redistribution levels of host component 905, for example to electrically couple package device 201 to one or more other IC dies, such as a memory IC die (not depicted), or another package device.

As further shown in FIG. 9, host component 905 may be further coupled to another host, such as a mother board or other PCB, by second level interconnects (SLI) 920. SLI 920 may comprise any solder (ball, bump, etc.) suitable for a given host board architecture (e.g., surface mount FR4, etc.). As illustrated in dashed line, one or more heat spreaders and/or heat sinks 950 may be further coupled to backside of IC die composite structure 901, which may be advantageous, for example, where IC die composite 901 comprises one or more CPU cores or other IC die of similar power density.

Although low-CTE dielectric build-up materials are described above in the context of their application with low-CTE IC device packages that may further comprise a package substrate of low-CTE material(s), such dielectric build-up materials also have other applications. For example, in alternative embodiments, low-CTE dielectric build-up materials in accordance with this disclosure are integrated with inorganic dielectric materials of an IC device package. For example, in some inter-die fill techniques an inorganic material is deposited (e.g., by PECVD) to mitigate stress-induced IC device failure and/or to increase the thermal ceiling of an IC device. Such inorganic materials (e.g., silicon dioxide, silicon nitride, silicon-oxy-nitride, silicon-carbon-nitride, etc.) often have a low-CTE (e.g., <10 ppm/K) and are therefore similarly compatible with the low-CTE dielectric build-up materials described herein. Accordingly, in some other implementations, a packaged IC device may comprise any of the low-CTE dielectric build-up materials described herein in direct contact with an inorganic dielectric material layer. In such embodiments, the low-CTE dielectric build-up materials described herein may again function as a good buffer layer between the inorganic dielectric material layer and an underlying substrate material.

FIG. 10 illustrates a mobile computing platform 1005 and a data server machine 1006 employing a packaged IC device including a low-CTE dielectric build-up material, for example as described elsewhere herein. Server machine 1006 may be any commercial server, for example including any number of high-performance computing platforms disposed within a rack and networked together for electronic data processing, which in the exemplary embodiment includes packaged IC device 801 with a low-CTE dielectric build-up material, for example as described elsewhere herein. The mobile computing platform 1005 may be any portable device configured for each of electronic data display, electronic data processing, wireless electronic data transmission, or the like. For example, the mobile computing platform 1005 may be any of a tablet, a smart phone, laptop computer, etc., and may include a display screen (e.g., a capacitive, inductive, resistive, or optical touchscreen), an integrated system 1010, and a battery 1015.

As illustrated in the expanded view 1020, packaged IC device 801 is further coupled to host component 905, along with one or more memory IC 1035. In some embodiments, an RF (wireless) integrated circuit (RFIC) 1025 including a wideband RF (wireless) transmitter and/or receiver may be further coupled to host component 905. RFIC 1025 has an output coupled to an antenna (not shown) to implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, and beyond.

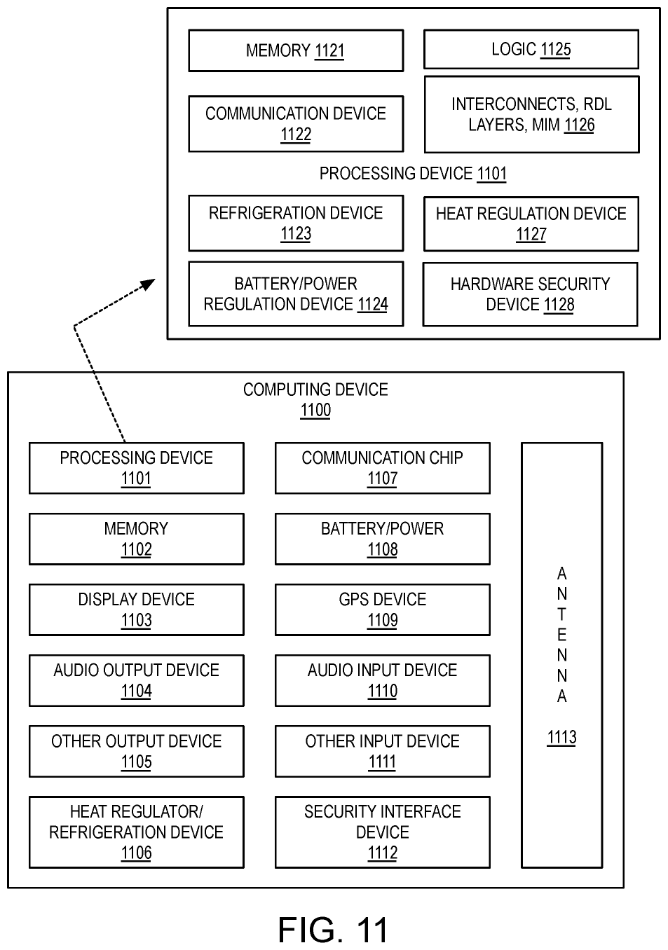

FIG. 11 is a block diagram of a cryogenically cooled computing device 1100 in accordance with some embodiments. For example, one or more components of computing device 1100 may include any of the devices or structures discussed elsewhere herein. A number of components are illustrated in FIG. 11 as included in computing device 1100, but any one or more of these components may be omitted or duplicated, as suitable for the application. In some embodiments, some or all of the components included in computing device 1100 may be attached to one or more printed circuit boards (e.g., a motherboard). In some embodiments, various ones of these components may be fabricated onto a single system-on-a-chip (SoC) die. Additionally, in various embodiments, computing device 1100 may not include one or more of the components illustrated in FIG. 11, but computing device 1100 may include interface circuitry for coupling to the one or more components. For example, computing device 1100 may not include a display device 1103, but may include display device interface circuitry (e.g., a connector and driver circuitry) to which display device 1103 may be coupled.

Computing device 1100 may include a processing device 1101 (e.g., one or more processing devices). As used herein, the term processing device or processor indicates a device that processes electronic data from registers and/or memory to transform that electronic data into other electronic data that may be stored in registers and/or memory. Processing device 1101 may include a memory 1121, a communication device 1122, a refrigeration/active cooling device 1123, a battery/power regulation device 1124, logic 1125, interconnects 1126 (i.e., optionally including redistribution layers (RDL) or metal-insulator-metal (MIM) devices), a heat regulation device 1127, and a hardware security device 1128.

Processing device 1101 may include one or more digital signal processors (DSPs), application-specific integrated circuits (ASICs), central processing units (CPUs), graphics processing units (GPUs), cryptoprocessors (specialized processors that execute cryptographic algorithms within hardware), server processors, or any other suitable processing devices.

Computing device 1100 may include a memory 1102, which may itself include one or more memory devices such as volatile memory (e.g., dynamic random-access memory (DRAM)), nonvolatile memory (e.g., read-only memory (ROM)), flash memory, solid state memory, and/or a hard drive. In some embodiments, memory 1121 includes memory that shares a die with processing device 1102. This memory may be used as cache memory and may include embedded dynamic random-access memory (eDRAM) or spin transfer torque magnetic random-access memory (STT-M RAM).

Computing device 1100 may include a heat regulator/refrigeration device 1106. Heat regulator/refrigeration device 1106 may maintain processing device 1101 (and/or other components of computing device 1100) at a predetermined low temperature during operation. This predetermined low temperature may be any temperature discussed elsewhere herein.

In some embodiments, computing device 1100 may include a communication chip 1107 (e.g., one or more communication chips). For example, the communication chip 1107 may be configured for managing wireless communications for the transfer of data to and from computing device 1100. The term “wireless” and its derivatives may be used to describe circuits, devices, systems, methods, techniques, communications channels, etc., that may communicate data through the use of modulated electromagnetic radiation through a nonsolid medium.

Communication chip 1107 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultramobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. Communication chip 1107 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. Communication chip 807 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). Communication chip 1107 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. Communication chip 1107 may operate in accordance with other wireless protocols in other embodiments. Computing device 1100 may include an antenna 1113 to facilitate wireless communications and/or to receive other wireless communications (such as AM or FM radio transmissions).

In some embodiments, communication chip 1107 may manage wired communications, such as electrical, optical, or any other suitable communication protocols (e.g., the Ethernet). As noted above, communication chip 1107 may include multiple communication chips. For instance, a first communication chip 1107 may be dedicated to shorter-range wireless communications such as Wi-Fi or Bluetooth, and a second communication chip 1107 may be dedicated to longer-range wireless communications such as GPS, EDGE, GPRS, CDMA, WiMAX, LTE, EV-DO, or others. In some embodiments, a first communication chip 1107 may be dedicated to wireless communications, and a second communication chip 1107 may be dedicated to wired communications.

Computing device 1100 may include battery/power circuitry 1108. Battery/power circuitry 1108 may include one or more energy storage devices (e.g., batteries or capacitors) and/or circuitry for coupling components of computing device 1100 to an energy source separate from computing device 1100 (e.g., AC line power).

Computing device 1100 may include a display device 1103 (or corresponding interface circuitry, as discussed above). Display device 1103 may include any visual indicators, such as a heads-up display, a computer monitor, a projector, a touchscreen display, a liquid crystal display (LCD), a light-emitting diode display, or a flat panel display, for example.

Computing device 800 may include an audio output device 1104 (or corresponding interface circuitry, as discussed above). Audio output device 1104 may include any device that generates an audible indicator, such as speakers, headsets, or earbuds, for example.

Computing device 1100 may include an audio input device 1110 (or corresponding interface circuitry, as discussed above). Audio input device 1110 may include any device that generates a signal representative of a sound, such as microphones, microphone arrays, or digital instruments (e.g., instruments having a musical instrument digital interface (MIDI) output).

Computing device 1100 may include a global positioning system (GPS) device 1109 (or corresponding interface circuitry, as discussed above). GPS device 1109 may be in communication with a satellite-based system and may receive a location of computing device 1100, as known in the art.

Computing device 1100 may include another output device 1105 (or corresponding interface circuitry, as discussed above). Examples include an audio codec, a video codec, a printer, a wired or wireless transmitter for providing information to other devices, or an additional storage device.

Computing device 1100 may include another input device 1111 (or corresponding interface circuitry, as discussed above). Examples may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

Computing device 1100 may include a security interface device 1112. Security interface device 1112 may include any device that provides security measures for computing device 1100 such as intrusion detection, biometric validation, security encode or decode, managing access lists, malware detection, or spyware detection. In some examples, security interface device 1112 comprises OTP ROM further including a via MIM fuse, for example as described elsewhere herein.

Computing device 1100, or a subset of its components, may have any appropriate form factor, such as a hand-held or mobile computing device (e.g., a cell phone, a smart phone, a mobile internet device, a music player, a tablet computer, a laptop computer, a netbook computer, an ultrabook computer, a personal digital assistant (PDA), an ultramobile personal computer, etc.), a desktop computing device, a server or other networked computing component, a printer, a scanner, a monitor, a set-top box, an entertainment control unit, a vehicle control unit, a digital camera, a digital video recorder, or a wearable computing device.

While certain features set forth herein have been described with reference to various implementations, this description is not intended to be construed in a limiting sense. Hence, various modifications of the implementations described herein, as well as other implementations, which are apparent to persons skilled in the art to which the present disclosure pertains are deemed to lie within the spirit and scope of the present disclosure.

It will be recognized that the disclosure is not limited to the embodiments so described but can be practiced with modification and alteration without departing from the scope of the appended claims. For example, the above embodiments may include specific combinations of features as further provided below.

In first examples, an integrated circuit (IC) device comprises a package substrate, a dielectric material over at least a first side of the package substrate, and a metallization level embedded within the dielectric material. The metallization level is to electrically couple an IC die affixed to the package substrate. The dielectric material comprises a filler material within a polymer resin. The filler material has a negative coefficient of thermal expansion (CTE) below a glass transition temperature (T_{g}) of the polymer resin.

In second examples, for any of the first examples the dielectric material has a coefficient of thermal expansion less than 10 ppm/K below T_{g}.

In third examples, for any of the first through second examples the filler material comprises a polycrystalline compound of a transition metal.

In fourth examples, for any of the first through third examples the filler material comprises a transition metal phosphate.

In fifth examples, for any of the fourth examples the transition metal phosphate comprises a chalcogen.

In sixth examples, for any of the fourth examples the transition metal phosphate comprises zirconium.

In seventh examples, for any of the first through sixth examples the filler material comprises particles having a diameter less than 5 μm and wherein the dielectric material comprises no more than 65 wt % of the filler material.

In eighth examples, for any of the first through seventh examples the polymer resin comprises no more than 50 wt % epoxy.

In ninth examples, for any of the eighth examples the polymer resin comprises at least 10 wt % polyimide.

In tenth examples, for any of the first through ninth examples the substrate is predominantly a glass, the dielectric material is in direct contact with a surface of the glass, and an IC die is electrically coupled to the metallization level.

In eleventh examples, an integrated circuit (IC) device comprises a package substrate, a dielectric material over at least a first side of the package substrate, an IC die, and a metallization level embedded within the dielectric material. The metallization level electrically couples the IC die to the package substrate and the dielectric material comprises a filler material within a polymer resin. The filler material comprises a transition metal.

In twelfth examples, for any of the eleventh examples the transition metal comprises zirconium and the filler material further comprises phosphorus.

In thirteenth examples, for any of the eleventh through twelfth examples the dielectric material comprises no more than 65 wt % of the filler material, and the polymer resin comprises no more than 50 wt % epoxy.

In fourteenth examples, for any of the thirteenth examples the polymer resin comprises at least 10 wt % polyimide.

In fifteenth examples, for any of the eleventh through fourteenth examples the substrate is predominantly a glass and wherein the dielectric material is in direct contact with a surface of the glass.

In sixteenth examples, for any of the eleventh through fifteenth examples the dielectric material is a first dielectric material and the filler is a first filler, the IC device further comprises a second dielectric material on a side of the first dielectric material opposite the substrate, and the first filler is absent from the second dielectric material.

In seventeenth examples, for any of the sixteenth examples the second dielectric material comprises a second filler of a different composition than the first filler, the polymer resin is a first polymer resin, and the second dielectric material comprises a second polymer resin of a different composition than the first polymer resin.

In eighteenth examples, a system comprises a host component and an integrated circuit (IC) device attached to the host component. The IC device comprises a package substrate, a dielectric material over at least a first side of the package substrate, an IC die, and a metallization level embedded within the dielectric material. The metallization level electrically coupling the IC die to the package substrate. The dielectric material comprises a filler material within a polymer resin. The filler material is polycrystalline and comprises a transition metal.

In nineteenth examples, for any of the eighteenth examples the filler material has a negative coefficient of thermal expansion (CTE) over a temperature range comprising 180° C. and 250° C.

In twentieth examples, for any of the eighteenth through nineteenth examples the system further comprises a power supply coupled to provide power to the IC die through the host component.

However, the above embodiments are not limited in this regard and, in various implementations, the above embodiments may include the undertaking of only a subset of such features, undertaking a different order of such features, undertaking a different combination of such features, and/or undertaking additional features than those features explicitly listed. The scope of the disclosure should therefore be determined with reference to the appended claims, along with the full scope of equivalents to which such claims are entitled.

What is claimed is:

1. An integrated circuit (IC) device, comprising:
a package substrate;
a dielectric material over at least a first side of the package substrate; and
a metallization level embedded within the dielectric material, the metallization level to electrically couple with an IC die affixed to the package substrate, wherein the dielectric material comprises a filler material within a polymer resin, and wherein the filler material has a negative coefficient of thermal expansion (CTE) below a glass transition temperature (T_{g}) of the polymer resin.

2. The IC device of claim 1, wherein the polymer resin has a coefficient of thermal expansion less than 10 ppm/K below T_{g}.

3. The IC device of claim 1, wherein the filler material comprises a polycrystalline compound of a transition metal.

4. The IC device of claim 1, wherein the filler material comprises a transition metal phosphate.

5. The IC device of claim 4, wherein the transition metal phosphate comprises a chalcogen.

6. The IC device of claim 4, wherein the transition metal phosphate comprises zirconium.

7. The IC device of claim 4, wherein the filler material comprises particles having a diameter less than 5 μm and wherein the dielectric material comprises no more than 65 wt % of the filler material.

8. The IC device of claim 1, wherein the polymer resin comprises no more than 50 wt % epoxy.

9. The IC device of claim 8, wherein the polymer resin comprises at least 10 wt % polyimide.

10. The IC device of claim 1, wherein:
the substrate is predominantly a glass and wherein the dielectric material is in direct contact with a surface of the glass; and
an IC die is electrically coupled to the metallization level.

11. An integrated circuit (IC) device, comprising:
a package substrate;
a dielectric material over at least a first side of the package substrate;
an IC die; and
a metallization level embedded within the dielectric material, the metallization level electrically coupling the IC die to the package substrate, wherein the dielectric material comprises a filler material within a polymer resin, and wherein the filler material comprises a transition metal.

12. The IC device of claim 11, wherein the transition metal comprises zirconium and the filler material further comprises phosphorus.

13. The IC device of claim 11, wherein:
the dielectric material comprises no more than 65 wt % of the filler material; and
the polymer resin comprises no more than 50 wt % epoxy.

14. The IC device of claim 13, wherein the polymer resin comprises at least 10 wt % polyimide.

15. The IC device of claim 11, wherein the substrate is predominantly a glass and wherein the dielectric material is in direct contact with a surface of the glass.

16. The IC device of claim 15, wherein:
the dielectric material is a first dielectric material and the filler is a first filler;
the IC device further comprises a second dielectric material on a side of the first dielectric material opposite the substrate; and
the first filler is absent from the second dielectric material.

17. The IC device of claim 16, wherein:
the second dielectric material comprises a second filler of a different composition than the first filler;
the polymer resin is a first polymer resin; and
the second dielectric material comprises a second polymer resin of a different composition than the first polymer resin.

18. A system comprising:
a host component; and
an integrated circuit (IC) device attached to the host component, the IC device comprising:
a package substrate;
a dielectric material over at least a first side of the package substrate;
an IC die; and
a metallization level embedded within the dielectric material, the metallization level electrically coupling the IC die to the package substrate, wherein the dielectric material comprises a filler material within a polymer resin, and wherein the filler material is polycrystalline and comprises a transition metal.

19. The system of claim 18, wherein the filler material has a negative coefficient of thermal expansion (CTE) over a temperature range comprising 180° C. and 250° C.

20. The system of claim 18, further comprising:
a power supply coupled to provide power to the IC die through the host component.
